(19) United States
(12) Patent Application Publication
(10) Pub. No.: US 2026/0013215 A1
(43) Pub. Date: Jan. 8, 2026

(54) TRANSISTORS AND SEMICONDUCTOR DEVICES INCLUDING THE SAME

(71) Applicant: Samsung Electronics Co., Ltd., Suwon-si (KR)

(72) Inventors: Donggun KIM, Suwon-si (KR); Harim CHOI, Suwon-si (KR); Hyojung KIM, Suwon-si (KR)

(21) Appl. No.: 19/243,916

(22) Filed: Jun. 20, 2025

(30) Foreign Application Priority Data
Jul. 4, 2024 (KR) 10-2024-0088103

(51) Int. Cl. H10D 84/83; H10D 62/10; H10D 62/832; H10D 64/68; H10D 84/01

(52) U.S. Cl. CPC H10D 84/8314; H10D 62/102; H10D 62/832; H10D 64/685; H10D 64/691; H10D 64/693; H10D 84/0144

(57) ABSTRACT

The transistor includes a gate structure on a substrate, and a source/drain region at an upper portion of the substrate adjacent to the gate structure and containing n-type impurities. The gate structure may include a gate interface pattern; a first gate dielectric pattern on the gate interface pattern and containing a compound of a first metal, wherein a dielectric constant of the compound of the first metal is greater than a dielectric constant of silicon oxide; a second gate dielectric pattern on the first gate dielectric pattern and containing an oxide or an oxynitride of a second metal different from the first metal, wherein an upper portion of the second gate dielectric pattern is doped with carbon of a first concentration; and a gate electrode on the second gate dielectric pattern.

### CROSS-REFERENCE TO RELATED APPLICATION

This application claims priority under 35 U.S.C. § 119 to Korean Patent Application No. 10-2024-0088103 filed on Jul. 4, 2024 in the Korean Intellectual Property Office, the disclosure of which is hereby incorporated by reference in its entirety.

### TECHNICAL FIELD

Example embodiments relate to a transistor and a semiconductor device including the same.

### DISCUSSION OF RELATED ART

In a semiconductor device, a gate structure may include a gate interface pattern and a gate electrode. Effective work function (eWF) is a value derived from flat band voltage (V_{fb}) which is measured through Cyclic Voltammetry (C-V) of the gate interface pattern and the gate electrode. An effective work function of the gate electrode is distinguished from an intrinsic work function of the gate electrode in that the effective work function of the gate electrode may be influenced by a material comprising the gate interface pattern, interface characteristics of the gate interface pattern and the gate electrode, etc. The effective work function of the gate electrode may be adjusted so that the gate structure may have an appropriate threshold voltage (Vₜₕ) value.

In a PMOS transistor, a work function difference between a first gate electrode of the PMOS transistor and an n-type semiconductor substrate may be negative ϕₘ-ϕₛ<0), and in the NMOS transistor, a work function difference between a second gate electrode of the NMOS transistor and a p-type semiconductor substrate may be positive (ϕₘ-ϕₛ>0). Accordingly, it may be advantageous to reduce an effective work function value of the second gate electrode of the NMOS transistor and to increase an effective work function value of the first gate electrode in the PMOS transistor to obtain an appropriate threshold voltage of each of the NMOS and PMOS transistors.

### SUMMARY

Example embodiments provide a transistor having improved characteristics.

Example embodiments provide a semiconductor device having improved characteristics.

According to example embodiments, there is provided a transistor. The transistor may include a gate structure on a substrate, and a source/drain region at an upper portion of the substrate adjacent to the gate structure and containing n-type impurities. The gate structure may include a gate interface pattern; a first gate dielectric pattern on the gate interface pattern and containing a compound of a first metal, wherein a dielectric constant of the compound of the first metal is greater than a dielectric constant of silicon oxide; a second gate dielectric pattern on the first gate dielectric pattern and containing an oxide or an oxynitride of a second metal different from the first metal, wherein an upper portion of the second gate dielectric pattern is doped with carbon of a first concentration; and a gate electrode on the second gate dielectric pattern.

According to example embodiments, there is provided a transistor. The transistor may include a gate structure and a source/drain region at an upper portion of the substrate adjacent to the gate structure. The gate structure may include a gate interface pattern, a first gate dielectric pattern on the gate interference pattern, a second gate dielectric pattern on the first gate dielectric pattern, and a gate electrode on the second gate dielectric pattern, wherein an upper portion of the second gate dielectric pattern is doped with a first impurity; and wherein a positive charge is formed at a portion of the gate interface pattern adjacent to a first interface of the gate interface pattern and the first gate dielectric pattern, and a negative charge is formed at a portion of the first gate dielectric pattern adjacent to the first interface, thereby forming a dipole at a vicinity of the first interface, and wherein a positive charge is formed at a portion of the second gate dielectric pattern adjacent to a second interface of the second gate dielectric pattern and the gate electrode, and a negative charge is formed at a portion of the gate electrode adjacent to the second interface, thereby forming a dipole at a vicinity of the second interface.

According to example embodiments, there is provided a semiconductor device. The semiconductor device may include a substrate, including a first region and a second region. The semiconductor device may include a first transistor, and epitaxial layer and a second transistor. The first transistor may include a first gate structure including a first gate interface pattern on the first region of the substrate, a first gate dielectric pattern on the first gate interface pattern, a second gate dielectric pattern on the first gate dielectric pattern, and a first gate electrode on the second gate dielectric pattern, wherein the first gate dielectric pattern contains a compound of a first metal, wherein a dielectric constant of the compound of the first metal is greater than a dielectric constant of silicon oxide, wherein the second gate dielectric pattern contains an oxide or an oxynitride of a second metal different from the first metal, and wherein an upper portion of the second gate dielectric pattern is doped with carbon; and a first source/drain region at an upper portion of the substrate adjacent to the first gate structure. The epitaxial layer may be disposed on the second region of the substrate. The second transistor may include a second gate structure including a second gate interface pattern on the epitaxial layer, a third gate dielectric pattern on the second gate interference pattern, and a second gate electrode on the third gate dielectric pattern, wherein the third gate dielectric pattern includes the compound of the first metal; and a second source/drain region at an upper portion of the epitaxial layer adjacent to the second gate structure.

A gate structure of an NMOS transistor according to example embodiments may include an interface pattern including an oxide of a first metal or an oxynitride of the first metal, and an upper portion of the interface pattern may be doped with carbon. Accordingly, an effective work function of the gate electrode of the NMOS transistor may be reduced, and a threshold voltage of the NMOS transistor may be appropriately adjusted.

### BRIEF DESCRIPTION OF THE DRAWINGS

FIGS. 1 and 2 are cross-sectional views illustrating a semiconductor device in accordance with example embodiments.

FIGS. 3 to 9 are cross-sectional views illustrating a method of manufacturing a semiconductor device according to example embodiments.

FIG. 10 is a cross-sectional view illustrating a semiconductor device in accordance with example embodiments.

FIG. 11 is a cross-sectional view illustrating a method of manufacturing semiconductor device in accordance with example embodiments.

### DETAILED DESCRIPTION

The above and other aspects and features of the transistors and the methods of manufacturing the same, and the semiconductor devices including the transistors and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. The terms “comprises,” “comprising,” “includes” and/or “including,” when used herein, specify the presence of stated elements, but do not preclude the presence of additional elements.

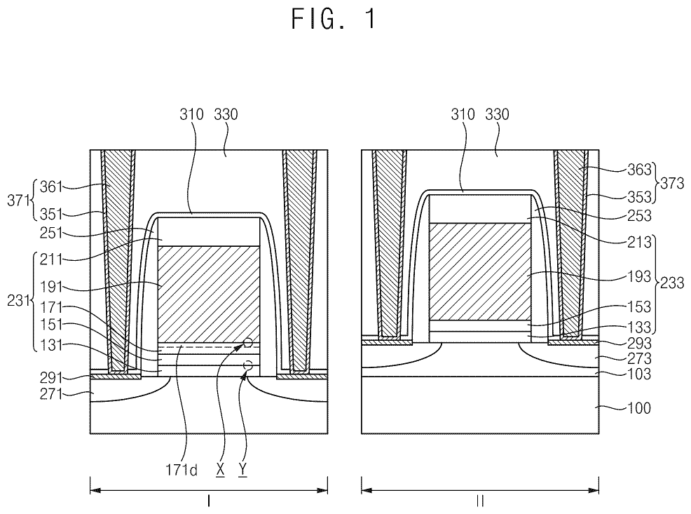

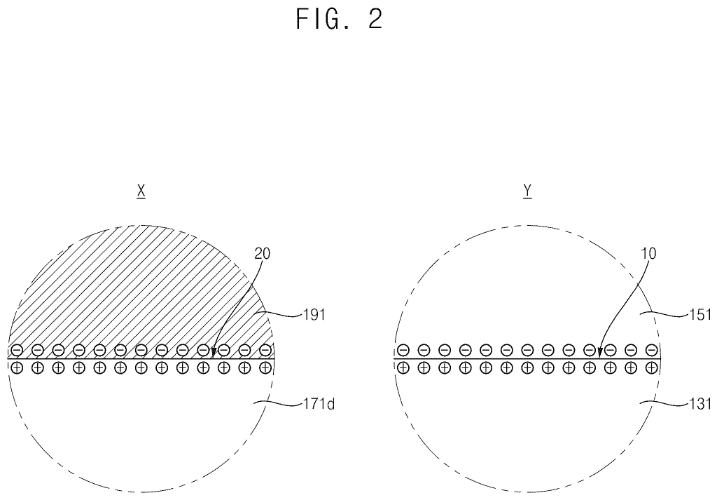

FIGS. 1 and 2 are cross-sectional views illustrating a semiconductor device in accordance with example embodiments, and FIG. 2 includes enlarged cross-sectional views of region X and region Y of FIG. 1.

Referring to FIGS. 1 and 2, the semiconductor device may include a first transistor and a second transistor on the substrate 100.

The semiconductor device may also include an epitaxial layer 103, a first gate spacer 251, a second gate spacer 253, a first ohmic contact pattern 291, a second ohmic contact pattern 293, an etch stop layer 310, an insulating interlayer 330, a first contact plug 371 and a second contact plug 373.

The substrate 100 may include a first region I and a second region II. The first and second regions I and II of the substrate 100 may be adjacent to each other or may be spaced apart from each other. In example embodiments, the first region I may be an NMOS region where NMOS transistors are located, and the second region II may be an PMOS region where PMOS transistors are located.

An isolation pattern, insulating the first region I of the substrate 100 and the second region II of the substrate 100 from each other, may be disposed on an upper portion of the substrate 100. The isolation pattern may include, for example, silicon oxide.

The substrate 100 may include a semiconductor material, for example, silicon, silicon germanium, etc. A first well region doped with, for example, p-type impurities may be disposed at the first region I of the substrate 100, and a second well region doped with, for example, n-type impurities may be disposed at the second region II of the substrate 100.

In example embodiments, in reference to a lower surface of the substrate 100, a height of an upper surface of the first region I of the substrate 100 may be substantially the same as a height of an upper surface in the second region II of the substrate 100.

The epitaxial layer 103 may be disposed on the second region II of the substrate 100. The epitaxial layer 103 may include a semiconductor material, for example, germanium, silicon-germanium, etc. The epitaxial layer 103 may be doped with n-type impurities and may form the second well region together with the second region II of the substrate 100.

In example embodiments, in reference to the lower surface of the substrate 100, a height of an upper surface of the epitaxial layer 103 may be greater than the height of the upper surface in the first region I of the substrate 100.

The first transistor may be disposed on the first region I of the substrate 100. The first transistor may include a first gate structure 231 and a first source/drain region 271.

The second transistor may be disposed on the second region I of the substrate 100. The second transistor may include a second gate structure 233 and a second source/drain region 273.

The first gate structure 231 may include a first gate interface pattern 131, a first gate dielectric pattern 151, a third gate dielectric pattern 171, a first gate electrode 191 and a first capping pattern 211 sequentially stacked on the first region I of the substrate 100.

The second gate structure 233 may include a second gate interface pattern 133, a second gate dielectric pattern 153, a second gate electrode 193 and a second capping pattern 213 sequentially stacked on the epitaxial layer 103 on the second region II of the substrate 100.

In example embodiments, in reference to the lower surface of the substrate 100, a height of a lower surface of the second gate structure 233 may be greater than a height of a lower surface of the first gate structure 231.

The first and second gate interface patterns 131 and 133 may include substantially a same material, for example, an oxide such as silicon oxide. The first gate interface pattern 131 may be disposed between the substrate 100 and the first gate dielectric pattern 151, and the second gate interface pattern 133 may be disposed between the substrate 100 and the second gate dielectric pattern 153. Accordingly, interface characteristics between the substrate 100 and each of the first and second gate dielectric patterns 151 and 153 may be improved, and hence, mobility of carriers may be improved.

The first and second gate dielectric patterns 151 and 153 may include, for example, a high dielectric material. A high dielectric material may refer to a material having a dielectric constant greater than that of silicon oxide (approximately 3.9), which is generally used as a gate interface pattern.

Each of the first and second gate dielectric patterns 151 and 153 may include a compound of a first metal, for example, an oxide of the first metal, a silicate of the first metal, a silicate nitride of the first metal, etc. The first metal may include hafnium (Hf), zirconium (Zr), or a combination thereof. The oxide of the first metal may include hafnium oxide, zirconium oxide, etc. The silicate of the first metal may include hafnium silicate (HfSiₓO_{y}), zirconium silicate (ZrSiₓO_{y}), etc. The silicate nitride of the first metal may include hafnium silicate nitride (HfSiₓO_{y}N_{z}), zirconium silicate nitride (ZrSiₓO_{y}N_{z}), etc.

The first gate dielectric pattern 151 may further include, for example, an oxide of a second metal. In comparison, the second gate dielectric pattern 153 may not further include the oxide of the second metal.

The third gate dielectric pattern 171 may include, for example, the oxide of the second metal, an oxynitride of the second metal, etc. The second metal may include, for example, lanthanum (La), scandium (Sc), or a combination thereof. The oxide of the second metal may include lanthanum oxide, scandium oxide, etc. The oxynitride of the second metal may include lanthanum oxynitride, scandium oxynitride, etc.

In example embodiments, an oxygen areal density of the oxide of the second metal may be smaller than an oxygen areal density of silicon oxide.

The second metal may diffuse from the third gate dielectric pattern 171 to the first gate dielectric pattern 151. Accordingly, the first gate dielectric pattern 151 may further include the oxide of the second metal which has a relatively low oxygen areal density.

Negatively charged oxygen may diffuse from the first gate interface pattern 131 that may contain silicon oxide with a relatively high oxygen areal density to the first gate dielectric pattern 151 that may contain the oxide of the second metal with a relatively low oxygen areal density. Accordingly, a negative charge may be formed at a portion of the first gate dielectric pattern 151 adjacent to a first interface 10 of the first gate interface pattern 131 and the first gate dielectric pattern 151, and a positive charge may be formed at a portion of the first gate interface pattern 131 adjacent to the first interface 10.

That is, a dipole may be induced at a vicinity of the first interface 10 of the first gate interface pattern 131 and the first gate dielectric pattern 151, and accordingly, the third gate dielectric pattern 171 may serve as a dipole inducing layer. As a dipole is induced at the vicinity of the first interface 10, effective work function of the first gate electrode 191 may decrease, and accordingly, the first transistor may have an appropriate threshold voltage.

An upper portion of the third gate dielectric pattern 171 may be referred to a doped region 171d that may contain a first impurity. In example embodiments, the first impurity may include carbon (C).

A negative charge may be formed at a portion of the first gate electrode 191 adjacent to a second interface 20 of the doped region 171d of the third gate dielectric pattern 171 and the first gate electrode 191, and a positive charge may be formed at a portion of the doped region 171d of the third gate dielectric pattern 171 adjacent to the second interface 20. That is, a dipole may be formed at a vicinity of the second interface 20 of the third gate dielectric pattern 171 and the first gate electrode 191. As a dipole is additionally induced at the vicinity of the second interface 20, the effective work function of the first gate electrode 191 may be further reduced, and accordingly, the first transistor may have an appropriate threshold voltage value.

In example embodiments, concentration of the first impurity of the doped region 171d of the third gate dielectric pattern 171 may be approximately 0.001 at % or more to approximately 5 at % or less. If the concentration of the first impurity exceeds 5 at %, interface characteristic of the second interface 20 of the doped region 171d of the third gate dielectric pattern 171 and the first gate electrode 191 may be deteriorated.

In example embodiments, the concentration of the second metal included in the doped region 171d of the third gate dielectric pattern 171 may be smaller than a concentration of the second metal included in regions of the third gate dielectric pattern 171 excluding the doped region 171d.

Each of the first and second gate electrodes 191 and 193 may include a low-resistance material, for example, a metal such as tungsten (W), a metal nitride such as titanium nitride (TiNₓ), etc. In example embodiments, the first and second gate electrodes 191 and 193 may include substantially a same material to each other.

The first and second capping patterns 211 and 213 may include substantially a same material, for example, an insulating nitride such as silicon nitride.

The first and second gate spacers 251 and 253 may cover sidewalls of the first and second gate structures 231 and 233, respectively. The first and second gate spacers 251 and 253 may include substantially a same material, for example, an oxide such as silicon oxide.

The first source/drain region 271 may be disposed at an upper portion of the first region I of the substrate 100 adjacent to the first gate structure 231. The first source/drain region 271 may include, for example, n-type impurities.

The second source/drain region 273 may be disposed at an upper portion of the epitaxial layer 103 adjacent to the second gate structure 233 on the second region II of the substrate 100. The second source/drain region 273 may include, for example, p-type impurities.

In the drawing, a lower surface of the second source/drain region 273 may be farther from the lower surface of the substrate 100 than a lower surface of the epitaxial layer 103, but the concept of the present invention is not limited thereto. That is, the lower surface of the second source/drain region 273 may be closer to the lower surface of the substrate 100 than the lower surface of the epitaxial layer 103.

First and second ohmic contact patterns 291 and 293 may disposed on the first and second source/drain regions 271 and 273, respectively. Each of the first and second ohmic contact patterns 291 and 293 may include a metal silicide, for example, titanium silicide, cobalt silicide, nickel silicide, etc.

The etch stop layer 310 may be disposed on the first and second gate structures 231 and 233, the first and second gate spacers 251 and 253 and the first and second ohmic contact patterns 291 and 293. The insulating interlayer 330 may be formed on the etch stop layer 310. The etch stop layer 310 may include a nitride, for example, silicon nitride. The insulating interlayer 330 may include an oxide, for example, silicon oxide.

The first contact plug 371 may extend through the insulating interlayer 330 and the etch stop layer 310 on the first region I of the substrate 100 to contact an upper surface of the first ohmic contact pattern 291. The first contact plug 371 may include a first conductive pattern 361 and a first barrier pattern 351 covering a sidewall and a lower surface thereof.

The second contact plug 373 may extend through the insulating interlayer 330 and the etch stop layer 310 on the second region II of the substrate 100 to contact an upper surface of the second ohmic contact pattern 293. The second contact plug 373 may include a second conductive pattern 363 and a second barrier pattern 353 covering a sidewall and a lower surface thereof.

Each of the first and second conductive patterns 361 and 363 may include a metal, for example, tungsten. Each of the first and second barrier patterns 351 and 353 may include a metal nitride, for example, titanium nitride.

As described above, the second metal included in the third gate dielectric pattern 171 may diffuse into the first gate dielectric pattern 151. Accordingly, dipole may be induced at the first interface 10 of the first gate interface pattern 131 and the first gate dielectric pattern 151, thereby reducing the effective work function of the first gate electrode 191 and appropriately adjusting the threshold voltage of the first transistor. However, there may be a limit to adjusting the threshold voltage of the first transistor just by increasing thickness of the third gate dielectric pattern 171.

Accordingly, in the concept of the present invention, the third gate dielectric pattern 171 may further include the doped region 171d which is doped with the first impurity. Accordingly, dipole may be additionally induced at the second interface 20 of the third gate dielectric pattern 171 and the first gate electrode 191, thereby further reducing the effective work function.

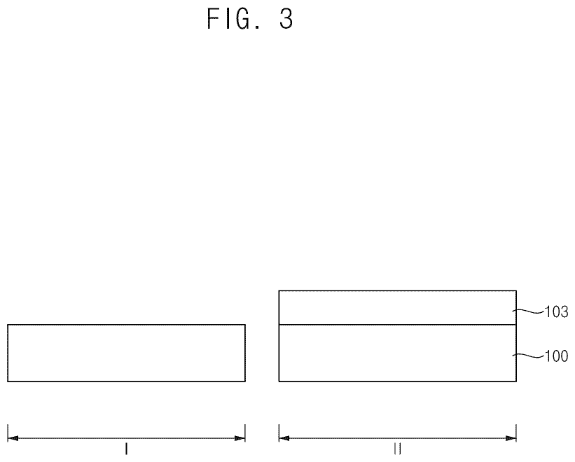

FIGS. 3 to 9 are cross-sectional views illustrating a method of manufacturing a semiconductor device according to example embodiments.

Referring to FIG. 3, after forming a first mask that may cover an upper surface of a first region I of the substrate 100 and expose an upper surface of a second region II of the substrate 100, an epitaxial growth process may be performed on the exposed upper surface of the second region II of the substrate 100 to form the epitaxial layer 103.

In example embodiments, the substrate 100 may include a semiconductor material, for example, germanium, silicon-germanium, etc., and the substrate 100 may be a p-type semiconductor substrate including a first well doped with p-type impurities.

The epitaxial layer 103 may include a semiconductor material, for example, germanium, silicon-germanium, etc. In example embodiments, an upper surface of the epitaxial layer 103 may be formed to be higher than the upper surface of the first region I of the substrate 100.

Thereafter, an ion implantation process may be performed on the second region II of the substrate 100 and the epitaxial layer 103 using n-type impurities. Thus, a second well region including a semiconductor material doped with n-type impurities may be formed on the second region II of the substrate 100 and the epitaxial layer 103. The first mask can be removed.

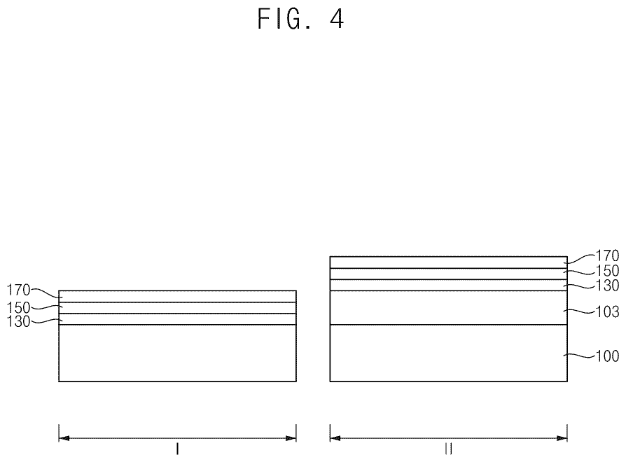

Referring to FIG. 4, a gate interface layer 130, a first gate dielectric layer 150 and a second gate dielectric layer 170 may be sequentially formed on the substrate 100 and the epitaxial layer 103.

The gate interface layer 130 may include an oxide, for example, silicon oxide.

The first gate dielectric layer 150 may include a high dielectric material having a dielectric constant greater than a dielectric constant of silicon oxide (approximately 3.9). Specifically, the first gate dielectric layer 150 may include, for example, an oxide of the first metal, a silicate of the first metal, or a silicate nitride of the first metal. The first metal may include, for example, hafnium (Hf), zirconium (Zr), etc. The oxide of the first metal may include, for example, hafnium oxide, zirconium oxide, etc. The silicate of the first metal may include, for example, hafnium silicate (HfSiₓO_{y}), zirconium silicate (ZrSiₓO_{y}), etc. The silicate nitride of the first metal may include, for example, hafnium silicate nitride (HfSiₓO_{y}N_{z}), zirconium silicate nitride (ZrSiₓO_{y}N_{z}), etc.

The second gate dielectric layer 170 may include, for example, an oxide of the second metal or an oxynitride of the second metal. The second metal may include, for example, lanthanum (La), scandium (Sc), etc.

In example embodiments, each of the gate interface layer 130, the first gate dielectric layer 150 and the second gate dielectric layer 170 may be formed by, for example, a Chemical Vapor Deposition (CVD) process, a Low-Pressure CVD (LPCVD) process, a Plasma-Enhanced CVD (PECVD) process, a Metal-Organic CVD (MOCVD) process, an Atomic Layer Deposition (ALD), a Plasma Enhanced ALD (PEALD) process, etc.

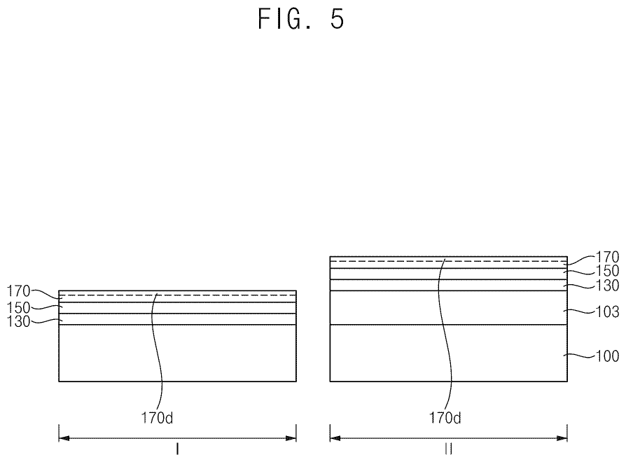

Referring to FIG. 5, a doped region 170d may be formed on an upper portion of the second gate dielectric layer 170 by performing an ion implantation process using a first impurity.

In example embodiments, the first impurity may include carbon (C).

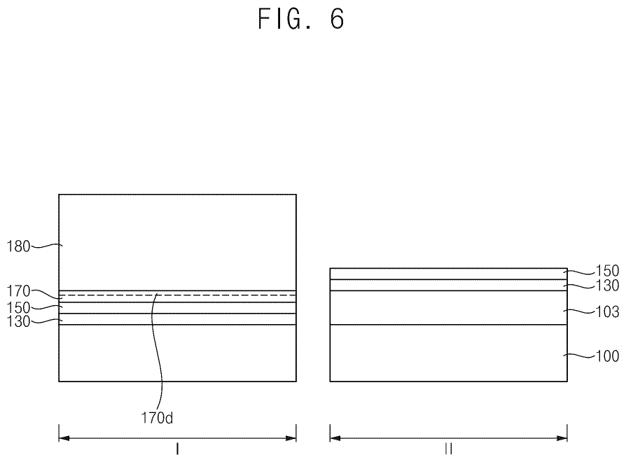

Referring to FIG. 6, after forming the second mask 180 covering a first portion of the second gate dielectric layer 170 on the first region I of the substrate 100 while exposing a second portion of the second gate dielectric layer 170 on the second region II of the substrate 100, the exposed second portion of the second gate dielectric layer 170 on the second region II of the substrate 100 may be removed.

Accordingly, the second gate dielectric layer 170 may remain only on the first region I of the substrate 100.

The second mask 180 may be removed.

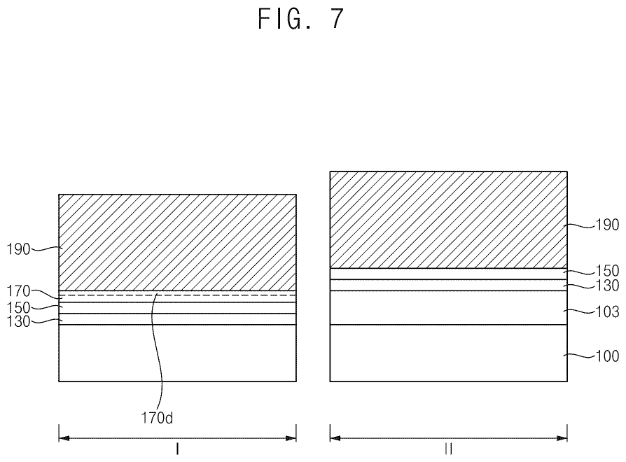

Referring to FIG. 7, a gate electrode layer 190 may be formed on an upper surface of the second gate dielectric layer 170 on the first region I of the substrate 100 and an upper surface of the first gate dielectric layer 150 on the second region II of the substrate 100.

The gate electrode layer 190 may include a metal, for example, tungsten (W) or a metal nitride, for example, titanium nitride (TiNₓ).

The gate interface layer 130, the first gate dielectric layer 150, the second gate dielectric layer 170 and the gate electrode layer 190 may together form a gate layer structure.

Hereinafter, the gate interface layer 130, the first gate dielectric layer 150, the second gate dielectric layer 170 and the gate electrode layer 190 on the first region I of the substrate 100 will be referred to as a first gate layer structure, and the gate interface layer 130, the first gate dielectric layer 150 and the gate electrode layer 190 on the second region I of the substrate 100 will be referred to as a second gate layer structure.

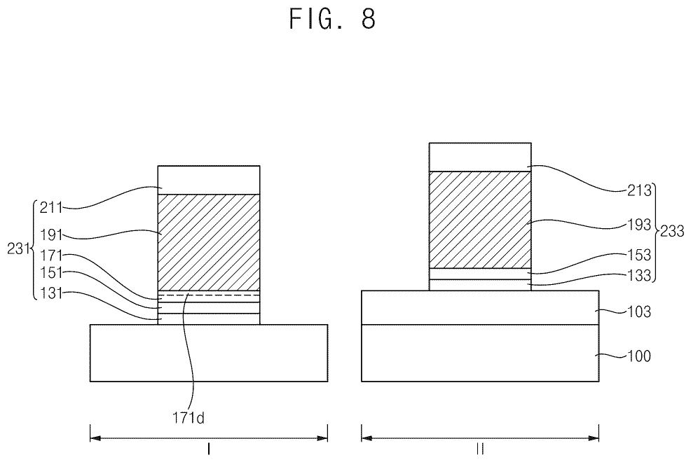

Referring to FIG. 8, after forming first and second capping patterns 211 and 213 on the first and second gate layer structures, respectively, an etching process using the first and second capping patterns 211 and 213 as an etch mask may be performed to pattern the first and second gate layer structures.

Accordingly, the gate interface layer 130, the first gate dielectric layer 150, the second gate dielectric layer 170 and the gate electrode layer 190 on the first region I of the substrate 100 may be respectively transformed to a first gate interface pattern 131, a first gate dielectric pattern 151, a third gate dielectric pattern 171 and the first gate electrode 191, and the gate interface layer 130, the first gate dielectric layer 150 and the gate electrode layer 190 on the second region II of the substrate 100 may be respectively transformed to a second gate interface pattern 133, a second gate dielectric pattern 153 and a second gate electrode 193.

The third gate dielectric pattern 171 may include a doped region 171d corresponding to the doped region 170d of the second gate dielectric layer 170.

In example embodiments, the first and second gate interface patterns 131 and 133 may be both formed from the gate interface layer 130 and thus may include substantially a same material, and the first and second gate electrodes 191 and 193 may be both formed from the gate electrode layer 190 and thus may include substantially a same material.

The first gate interface pattern 131, the first gate dielectric pattern 151, the third gate dielectric pattern 171, the first gate electrode 191 and the first capping pattern 211 sequentially stacked on the first region I of the substrate 100 may together form a first gate structure 231. The second gate interface pattern 133, the second gate dielectric pattern 153, the second gate electrode 193 and the second capping pattern 213 sequentially stacked on the epitaxial layer 103 of the second region II of the substrate 100 may together form the second gate structure 233.

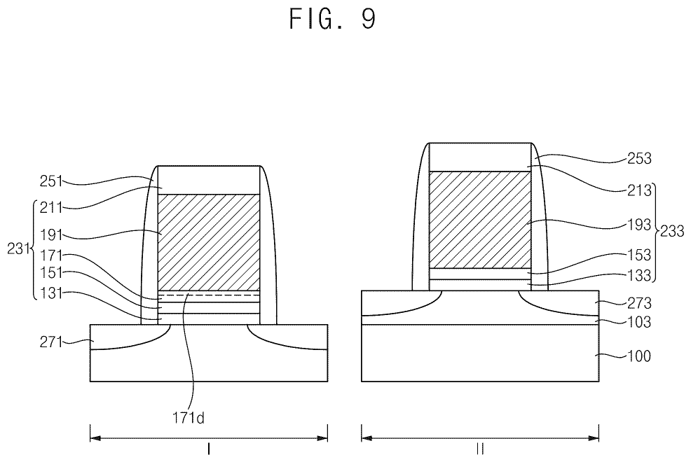

Referring to FIG. 9, a gate spacer layer may be, for example, conformally formed on the upper surface of the substrate 100, the upper surface of the epitaxial layer 103, a sidewall and an upper surface of the first gate structure 231 and a sidewall and an upper surface of the second gate structure 233, and an anisotropic etching process may be performed on the gate spacer layer to form first and second gate spacers 251 and 253 covering the sidewalls of the first and second gate structures 231 and 233, respectively.

An ion implantation process may be performed on an upper portion of the first region I of the substrate 100 adjacent to the first gate structure 231 to form a first source/drain region 271, and an ion implantation process may be performed on an upper portion of the epitaxial layer 103 adjacent to the second gate structure 233 to form a second source/drain region 273. In example embodiments, the first source/drain region 271 may be formed to include n-type impurities, and the second source/drain region 273 may be formed to include p-type impurities.

The first gate structure 231 and the first source/drain region 271 may together form a first transistor, and the second gate structure 233 and the second source/drain region 273 may together form a second transistor.

Referring to FIG. 1 again, first and second ohmic contact patterns 291 and 293 may be respectively formed on upper surfaces of the first and second source/drain regions 271 and 273.

In example embodiments, the first and second ohmic contact patterns 291 and 293 maybe formed by forming a first metal layer on the first and second gate structures 231 and 233, the first and second gate spacers 251 and 253 and the first and second source/drain regions 271 and 273, performing a heat-treating process on the first metal layer, and removing an unreacted portion of the first metal layer. The first metal layer may include a metal, for example, titanium, cobalt, nickel.

An etch stop layer 310 and insulating interlayer 330 may be sequentially formed on the first and second ohmic contact patterns 291 and 293, the first and second gate spacers 251 and 253 and the first and second gate structures 231 and 233.

A first opening may be formed to extend through the insulating interlayer 330 and the etch stop layer 310 to expose an upper surface of the first ohmic contact pattern 291 on the first region I of the substrate 100, and a first contact plug 371 may be formed within the first opening. A second opening may be formed to extend through the insulating interlayer 330 and the etch stop layer 310 to expose an upper surface of the second ohmic contact pattern 293 on the second region II of the substrate 100, and a second contact plug 373 may be formed within the second opening.

In example embodiments, the first contact plug 371 may be formed to include a first conductive pattern 361 and a first barrier pattern 351 covering a sidewall and a lower surface thereof, and the second contact plug 373 may be formed to include a second conductive pattern 363 and a second barrier pattern 353 covering a sidewall and a lower surface thereof.

Thereafter, manufacturing of the semiconductor device may be completed by forming contact plugs and wirings electrically connected to various structures on the substrate 100.

In the method of manufacturing the semiconductor device, an ion implantation process may be performed to dope the first impurity into the upper portion of the second gate dielectric layer 170, and accordingly, the third gate dielectric pattern 171 may be formed to further include the doped region 171d. By the doped region 171d of the third gate dielectric pattern 171, a dipole may be induced at an interface of the third gate dielectric pattern 171 and the first gate electrode 191, and effective work function of the first gate electrode 191 may decrease. Accordingly, threshold voltage of the first transistor may be appropriately adjusted.

Additionally, in the method of manufacturing the semiconductor device, the second portion of the second gate dielectric layer 170 on the second region II of the substrate 100 including an oxide of the second metal or an oxynitride of the second metal may be removed.

If the second portion of the second gate dielectric layer 170 on the second region II of the substrate 100 is not removed, the second gate structure 233 may be formed to further include a fourth gate dielectric pattern containing an oxide of the second metal or an oxynitride of the second metal, and to compensate for the decrease of effective work function of the second gate electrode 193 due to the fourth gate dielectric pattern, a third gate electrode may be additionally formed on the fourth gate dielectric pattern. In this case, level difference between the first and second gate structures 231 and 233 may increase, thereby increasing difficulty of manufacturing the semiconductor device.

However, in example embodiments, since the second portion of the second gate dielectric layer 170 on the second region II of the substrate 100 is removed, there is no need to additionally form the third gate electrode, thereby alleviating the level difference between the first and second gate structures 231 and 233. Accordingly, difficulty of manufacturing the semiconductor device may be reduced.

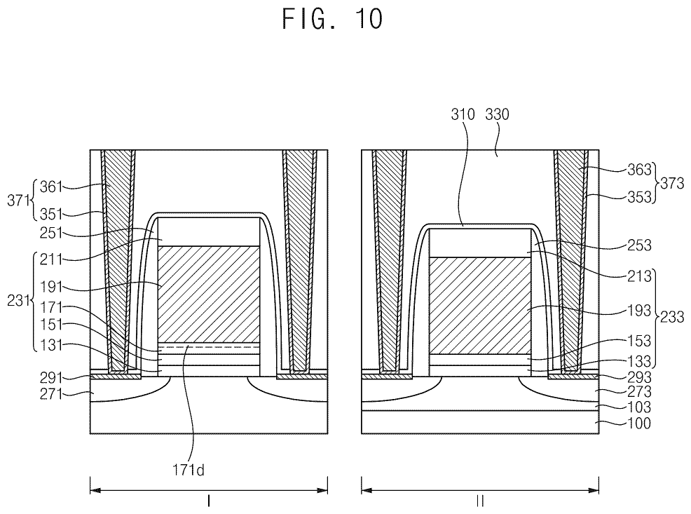

FIG. 10 is a cross-sectional view illustrating a semiconductor device in accordance with example embodiments. The semiconductor device may be substantially the same as or similar to a semiconductor device of FIG. 1, except for a height of the epitaxial layer 103, and thus repeated explanations are omitted herein.

Referring to FIG. 10, in reference to the lower surface of the substrate 100, the height of the upper surface in the second region II of the substrate 100 may be lower than the height of the upper surface in the first region I of the substrate 100.

In the drawing, in reference to the lower surface of the substrate 100, the height of the lower surface of the second gate structure 233 and the height of the lower surface of the first gate structure 231 are illustrated to be substantially the same, but the concept of the present invention is not limited thereto. That is, depending on a thickness in the vertical direction of the epitaxial layer 103, the height of the lower surface of the second gate structure 233 may be higher or lower than the height of the lower surface of the first gate structure 231.

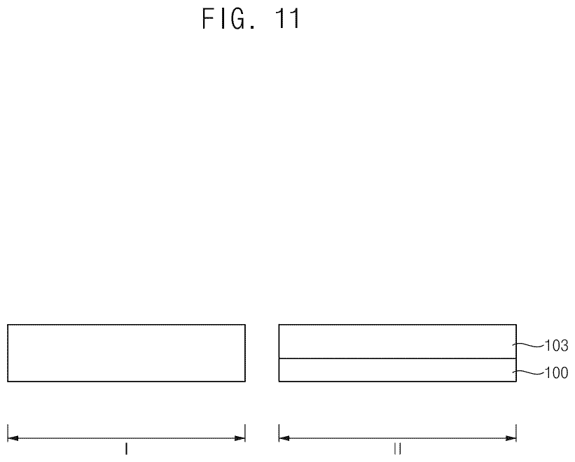

FIG. 11 is a cross-sectional view illustrating a method of forming a semiconductor device in accordance with example embodiments. This method may include processes substantially the same as or similar to those illustrated with reference to FIGS. 1 to 9, and thus repeated explanations thereof are omitted herein.

Referring to FIG. 11, an upper portion of the second region II of the substrate 100 may planarized by, for example, a grinding process, or, for example, a chemical mechanical polishing (CMP) process, an etch back process, etc.

Accordingly, in reference to the lower surface of the substrate 100, the height of the upper surface in the second region II of the substrate 100 may be formed to be lower than the height of the upper surface in the first region I of the substrate 100.

Thereafter, manufacturing of the semiconductor device may be completed by performing processes substantially the same as or similar to the processes illustrated with reference to FIGS. 3 to 9.

While the present inventive concepts have been shown and described with reference to example embodiments thereof, it will be understood by those of ordinary skill in the art that various changes in form and details may be made thereto without departing from the spirit and scope of the present inventive concepts as set forth by the following claims.

What is claimed is:

1. A transistor comprising:
a gate structure on a substrate, the gate structure comprising:
a gate interface pattern;
a first gate dielectric pattern on the gate interface pattern and containing a compound of a first metal, wherein a dielectric constant of the compound of the first metal is greater than a dielectric constant of silicon oxide;
a second gate dielectric pattern on the first gate dielectric pattern and containing an oxide or an oxynitride of a second metal different from the first metal, wherein an upper portion of the second gate dielectric pattern is doped with carbon of a first concentration; and
a gate electrode on the second gate dielectric pattern; and
a source/drain region on an upper portion of the substrate, adjacent to the gate structure, and containing n-type impurities.

2. The transistor of claim 1, wherein the first concentration of carbon is about 0.001 at % or more and about 5 at % or less.

3. The transistor of claim 1, wherein the second metal comprises lanthanum, scandium, or a combination thereof.

4. The transistor of claim 1, wherein the first gate dielectric pattern further comprises an oxide of the second metal.

5. The transistor of claim 1, wherein an oxygen areal density of the oxide of the second metal is smaller than an oxygen areal density of silicon oxide.

6. The transistor of claim 1, wherein the compound of the first metal comprises an oxide of the first metal, a silicate of the first metal or a silicate nitride of the first metal.

7. A transistor comprising:
a gate structure on a substrate, the gate structure comprising: a gate interface pattern, a first gate dielectric pattern on the gate interface pattern, a second gate dielectric pattern on the first gate dielectric pattern, and a gate electrode on the second gate dielectric pattern; wherein an upper portion of the second gate dielectric pattern is doped with a first impurity; and
a source/drain region at an upper portion of the substrate adjacent to the gate structure,
wherein a positive charge is formed at a portion of the gate interface pattern adjacent to a first interface of the gate interface pattern and the first gate dielectric pattern, and a negative charge is formed at a portion of the first gate dielectric pattern adjacent to the first interface, thereby forming a dipole at a vicinity of the first interface, and
wherein a positive charge is formed at a portion of the second gate dielectric pattern adjacent to a second interface of the second gate dielectric pattern and the gate electrode, and a negative charge is formed at a portion of the gate electrode adjacent to the second interface, thereby forming a dipole at a vicinity of the second interface.

8. The transistor of claim 7, wherein the source/drain region comprises n-type impurities.

9. The transistor of claim 7, wherein the first impurity comprises carbon.

10. The transistor of claim 9, wherein a concentration of the first impurity is about 0.001 at % or more and about 5 at % or less.

11. The transistor of claim 7, wherein the first gate dielectric pattern comprises a compound of a first metal, and the second gate dielectric pattern comprises an oxide or an oxynitride of a second metal different from the first metal, and wherein a dielectric constant of the compound of the first metal is greater than a dielectric constant of silicon oxide.

12. The transistor of claim 11, wherein the second metal comprises lanthanum, scandium, or a combination thereof.

13. The transistor of claim 11, wherein the first gate dielectric pattern further comprises an oxide of the second metal.

14. The transistor of claim 11, wherein an oxygen areal density of an oxide of the second metal is smaller than an oxygen areal density of silicon oxide.

15. A semiconductor device comprising:
a substrate, comprising a first region and a second region;
a first transistor comprising:
a first gate structure comprising a first gate interface pattern on the first region of the substrate, a first gate dielectric pattern on the first gate interface pattern, a second gate dielectric pattern on the first gate dielectric pattern, and a first gate electrode on the second gate dielectric pattern, wherein the first gate dielectric pattern contains a compound of a first metal, wherein a dielectric constant of the compound of the first metal is greater than a dielectric constant of silicon oxide, wherein the second gate dielectric pattern contains an oxide or an oxynitride of a second metal different from the first metal, and wherein an upper portion of the second gate dielectric pattern is doped with carbon; and
a first source/drain region at an upper portion of the substrate adjacent to the first gate structure;
an epitaxial layer on the second region of the substrate; and
a second transistor comprising:
a second gate structure comprising a second gate interface pattern on the epitaxial layer, a third gate dielectric pattern on the second gate interference pattern, and a second gate electrode on the third gate dielectric pattern, wherein the third gate dielectric pattern comprises the compound of the first metal; and
a second source/drain region at an upper portion of the epitaxial layer adjacent to the second gate structure.

16. The semiconductor device of claim 15, wherein the first transistor is a NMOS transistor and the second transistor is a PMOS transistor.

17. The semiconductor device of claim 15, wherein the epitaxial layer comprises germanium or silicon-germanium.

18. The semiconductor device of claim 15, wherein the first gate electrode and the second gate electrode comprise substantially a same material.

19. The semiconductor device of claim 15, wherein the first gate dielectric pattern further comprises an oxide of the second metal, and an oxygen areal density of the oxide of the second metal is smaller than an oxygen areal density of silicon oxide.

20. The semiconductor device of claim 15, wherein a positive charge is formed at a portion of the first gate interface pattern adjacent to a first interface of the first gate interface pattern and the first gate dielectric pattern, and a negative charge is formed at a portion of the first gate dielectric pattern adjacent to the first interface, thereby forming a dipole at a vicinity of the first interface, and
wherein a positive charge is formed at a portion of the second gate dielectric pattern adjacent to a second interface of the second gate dielectric pattern and the first gate electrode, and a negative charge is formed at a portion of the first gate electrode adjacent to the second interface, thereby forming a dipole at a vicinity of the second interface.
